(19) United States
(12) Patent Application Publication
(10) Pub. No.: US 2025/0266268 A1
(43) Pub. Date: Aug. 21, 2025

(54) FLUID ROUTING FOR A VACUUM PUMPING SYSTEM

(71) Applicant: Edwards Limited, Burgess Hill (GB)

(72) Inventor: Julian Richard Dean, Burgess Hill (GB)

(21) Appl. No.: 18/859,368

(22) PCT Filed: Mar. 22, 2023
(86) PCT No.: PCT/GB2023/050728

§ 371 Date: Oct. 23, 2024

(30) Foreign Application Priority Data
May 17, 2022 (GB) 2207187.2

(51) Int. Cl. H01L 21/67; F04D 19/04

(52) U.S. Cl. CPC H01L 21/67017; F04D 19/04

(57) ABSTRACT

A fluid routing module (104) for a vacuum pumping system (100), the fluid routing module (104) comprising: a first fluid inlet (110a); a first fluid outlet (114a); a first fluid line (200) coupled between the first fluid inlet (110a) and the fluid outlet (114a); and a restrictor module (212) disposed along the first fluid line (200) between the first fluid inlet (110a) and the first fluid outlet (114a), the restrictor module (212) being configured to variably restrict a flow of fluid between the first fluid inlet (110a) and the first fluid outlet (114a).

This application is a national stage entry under 35 U.S.C. § 371 of International Application No. PCT/GB2023/050728, filed Mar. 22, 2023, which claims the benefit of GB Application No. 2207187.2, filed May 17, 2022, the entire contents of each of which are incorporated herein by reference.

### TECHNICAL FIELD

The present disclosure relates to fluid routing for use with vacuum pumping systems, including but not limited to vacuum systems for pumping fluids from semiconductor processing tools.

### BACKGROUND

Semiconductor fabrication plants fabricate integrated circuit chips. In the fabrication of such devices, wafers are processed through a number of different processing stations, including stations at which the wafer undergoes, for example, chemical vapor deposition, physical vapor deposition, implant, etch and lithography processes. Many of these processes involve the use of a gaseous ambient and often involve the use of high vacuum and reduced gas pressures.

Vacuum pumps are used to provide these reduced gas pressures in process chambers, provide chamber evacuation, and maintain flows of processing gases.

### SUMMARY

When the pressure inside a chamber of a semiconductor processing tool is not at working vacuum, for example after a process chamber has been vented to atmospheric pressure to enable service or maintenance, a so-called “pump-down event” is performed to establish the reduced gas pressure in the chamber. A pump-down event involves pumping gas from the chamber so as to reduce the pressure therein to the reduced gas pressure.

Similarly, when the pressure inside a pumping chamber of a vacuum pump (e.g., a turbopump) is at atmospheric pressure, for example after the vacuum pump has been deactivated to enable service or maintenance, a pump-down event is performed to establish a reduced gas pressure in the pumping chamber of that vacuum pump.

Vacuum and abatement systems may be used to pump gas from multiple process chambers of a semiconductor processing tool simultaneously using a common pump via a common manifold. The present inventors have realised that in such systems, because multiple chambers and/or multiple turbopumps may be fluidly connected to a common manifold, performing a pump-down event for one of those chambers and/or turbopumps may affect the conditions within others of those chambers. For example, a pump-down event performed on one chamber may cause highly undesirable fluctuations in other chambers connected to the same manifold.

Aspects of the present disclosure provide a valve module for controlling fluid from multiple chambers of a semiconductor processing tool in such a way that these deficiencies are reduced or eliminated.

In a first aspect, there is provided a fluid routing module for a vacuum pumping system. The fluid routing module comprises: a first fluid inlet; a first fluid outlet; a first fluid line coupled between the first fluid inlet and the fluid outlet; and a restrictor module disposed along the first fluid line between the first fluid inlet and the first fluid outlet, the restrictor module being configured to variably restrict a flow of fluid between the first fluid inlet and the first fluid outlet.

The restrictor module may comprise a plurality of restrictors disposed along the first fluid line between the first fluid inlet and the fluid outlet, the plurality of restrictors being arranged in parallel with each other, each restrictor of the plurality of restrictors being configured to restrict a flow of fluid therethrough. The fluid routing module may further comprise means configured to selectably direct a fluid flow through a selected one or more restrictors of the plurality of restrictors while preventing the flow of fluid through the other restrictors of the plurality of restrictors. The means configured to selectably direct a fluid flow through a selected one or more restrictors may comprise a plurality of valves, each valve in the plurality of valves being arranged in series with a respective restrictor of the plurality of restrictors. The fluid routing module may further comprise: a bypass line arranged in parallel with the restrictor module whereby to allow a flow of fluid to bypass the plurality of restrictors; and one or more further valves configured to selectably direct a fluid flow through either the bypass line or the plurality of restrictors. The fluid routing module of may further comprise a valve controller configured to control operation of a valve. Each restrictor of the plurality of restrictors may be configured to restrict a flow of fluid therethrough to a different extent. Each restrictor of the plurality of restrictors may comprise a flow restricting orifice having a different respective diameter.

The fluid routing module may further comprise a vacuum pump disposed along the first fluid line between the first fluid inlet and the restrictor module. The vacuum pump may be a turbopump.

The fluid routing module may further comprise: a second fluid inlet; a second fluid outlet; a second fluid line coupled between the second fluid inlet and the fluid outlet; and one or more valves disposed along the second fluid line.

In a further aspect, there is provided a system comprising: a semiconductor processing tool comprising a processing chamber; the fluid routing module of any preceding aspect, wherein the first fluid inlet is fluidly coupled to the processing chamber; and a vacuum pump operatively coupled to the first fluid outlet.

The semiconductor processing tool may further comprise one or more further processing chambers. The system may further comprise one or more further fluid routing modules, each further fluid routing module being a fluid routing module in accordance with any preceding aspect, wherein the first fluid inlets of each further fluid routing module are fluidly coupled to a respective further processing chamber. The system may further comprise a fluid line manifold, wherein the first fluid outlets of the fluid routing module and each of the further fluid routing modules are fluidly coupled to the fluid line manifold. The vacuum pump may be operatively coupled to the fluid line manifold.

The second fluid inlet may be fluidly coupled to the processing chamber. The system may further comprise a further vacuum pump operatively coupled to the second fluid outlet.

In a further aspect, there is provided a method for routing a fluid through a fluid routing module. The fluid routing module may be in accordance with any preceding aspect. The method comprises: receiving a flow of a fluid at the first fluid inlet; variably restricting, by the restrictor module, the fluid through the restrictor module; and thereafter, the fluid flowing out of the first fluid outlet.

The fluid routing module may further comprise: a vacuum pump disposed along the first fluid line between the first fluid inlet and the restrictor module; a bypass line arranged to allow a flow of fluid to a flow restricting portion of the restrictor module; and means configured to selectably direct a fluid flow through the bypass line. The method may further comprise, responsive to one or more conditions being satisfied, controlling the further means to cause the fluid to flow through the bypass line, thereby bypassing the flow restricting portion of the restrictor module, The one or more conditions may comprise a condition that a pressure in a pumping chamber of the vacuum pump is below a threshold pressure.

In any of the above aspects, there may be multiple fluid routing modules, i.e. there may be multiple first fluid inlets, multiple first fluid lines, and multiple first fluid outlets. In addition, there may be a fluid line manifold. The multiple first fluid outlets of the multiple fluid routing modules may be fluidly coupled to the fluid line manifold.

### BRIEF DESCRIPTION OF DRAWINGS

FIG. 1 is a schematic illustration (not to scale) of a semiconductor fabrication facility;

FIG. 2 is a schematic illustration (not to scale) showing further details of a pumping module of the semiconductor fabrication facility;

FIG. 3 is a schematic illustration (not to scale) showing further details of a restrictor module of the semiconductor fabrication facility;

FIG. 4 is a process flow chart showing steps of a process of pumping gas in the semiconductor fabrication facility;

FIG. 5 is a process flow chart showing steps of a process of operating restrictor valves; and

FIG. 6 is a schematic illustration (not to scale) illustrating operation of the restrictor valves.

### DETAILED DESCRIPTION

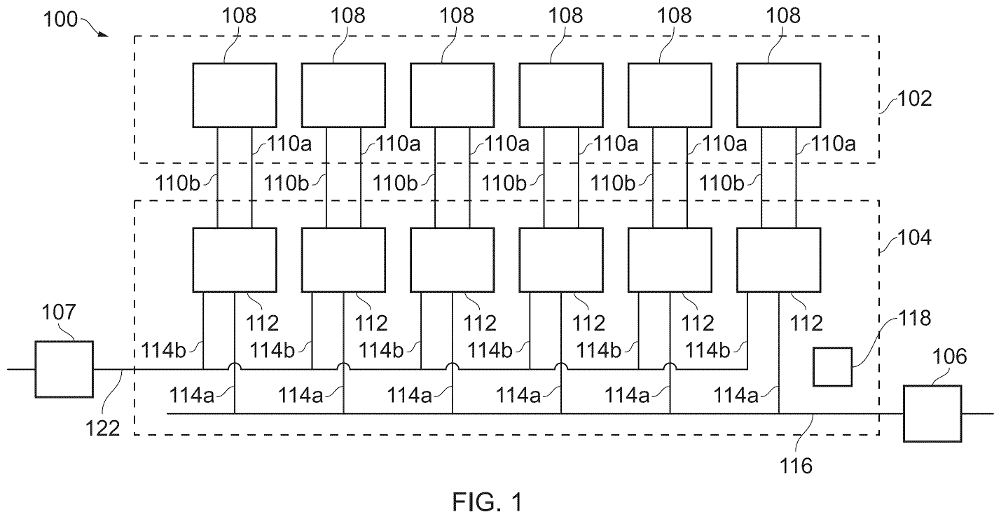

FIG. 1 is a schematic illustration (not to scale) of a semiconductor fabrication facility 100, in accordance with an example.

The semiconductor fabrication facility 100 comprises a semiconductor processing tool 102, a fluid routing module 104, a first vacuum pump 106, and a second vacuum pump 107.

The semiconductor processing tool 102 comprises a plurality of process chambers 108 in which semiconductor wafers undergo respective processes. Examples of such processes include, but are not limited to, chemical vapor deposition, physical vapor deposition, implant, etch and lithography processes.

The first vacuum pump 106 is configured to pump fluids (i.e. process gases) out of the process chambers 108 of the semiconductor processing tool 102 via the fluid routing module 104.

The second vacuum pump 107 is configured to pump fluids (i.e. process gases) out of the process chambers 108 of the semiconductor processing tool 102 via the fluid routing module 104.

The fluid routing module 104 comprises a plurality of fluid inlets (in particular, a plurality of first fluid inlets 110a and a plurality of second fluid inlets 110b), a plurality of pumping modules 112, a plurality of fluid outlets (in particular, a plurality of first fluid outlets 114a and a plurality of second fluid outlets 114b), a first fluid line manifold 116, and a second fluid line manifold 122.

A respective pair of first and second fluid inlets 110a, 110b is fluidly connected between a respective process chamber 108 and a respective pumping module 112, such that fluid may flow from that process chamber 108 to that pumping module 112 via either or both of those first and second fluid inlets 110a, 110b.

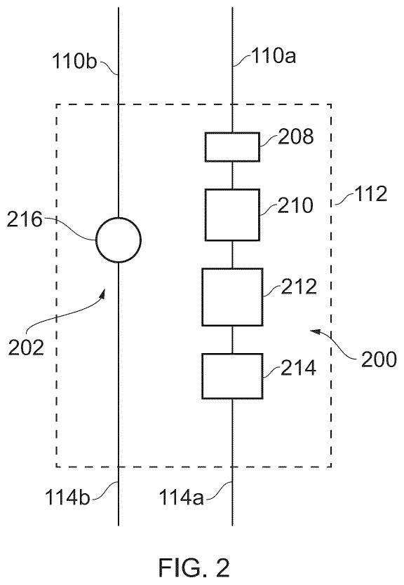

The pumping modules 112 will be described in more detail later below with reference to FIG. 2.

Each pumping module 112 is fluidly connected to the first fluid line manifold 116 by a respective first fluid outlet 114a, such that fluid may flow from the pumping module 112 to the first fluid line manifold 116. Each pumping module 112 is fluidly connected to the second fluid line manifold 122 by a respective second fluid outlet 114b, such that fluid may flow from the pumping module 112 to the second fluid line manifold 122.

The first fluid line manifold 116 is fluidly connected between the plurality of first fluid outlets 114a and the first vacuum pump 106.

The second fluid line manifold 122 is fluidly connected between the plurality of second fluid outlets 114b and the second vacuum pump 107.

The fluid routing module 104 further comprises a valve controller 118.

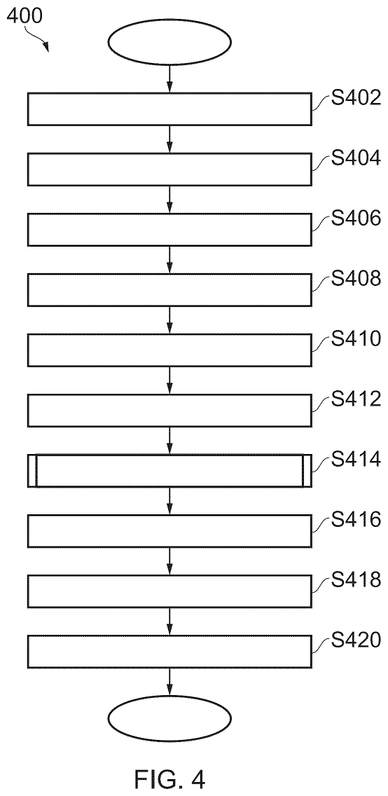

The valve controller 118 is operatively coupled, via respective pneumatic lines and/or electrical connections (not shown), to each of a plurality of valves comprised in the pumping modules 112. These valves are described in more detail later below with reference to FIG. 2. As described in more detail later below with reference to FIG. 4, the valve controller 118 is configured to control operation of the valves of the pumping modules 112, for example by transferring pneumatic fluid thereto via pneumatic lines.

FIG. 2 is a schematic illustration (not to scale) showing further details of a pumping module 112. In this example, the pumping modules 112 of the fluid routing module 104 are substantially the same as each other.

In this example, the first fluid inlet 110a and the second fluid inlet 110b are fluid inlets of the pumping module 112. Also, the first fluid outlet 114a and the second fluid outlet 114b are fluid outlets of the pumping module 112.

The pumping module 112 comprises a first fluid line 200 coupled between the first fluid inlet 110a and the first fluid outlet 114a, and a second fluid line 202 coupled between the second fluid inlet 110b and the second fluid outlet 114b.

The pumping module 112 comprises an automatic pressure control (APC) module 208, a turbopump 210, a restrictor module 212, a pressure sensor 214, and a valve 216.

The APC module 208, the turbopump 210, the restrictor module 212, and the pressure sensor 214 are disposed along the first fluid line 200. The APC module 208 is arranged between the first fluid inlet 110a and the turbopump 210. The turbopump 210 is arranged between the APC module 208 and the restrictor module 212. The restrictor module 212 is arranged between the turbopump 210 and the pressure sensor 214. The pressure sensor 214 is arranged between the restrictor module 212 and the first fluid outlet 114a.

The valve 216, which may be considered to be a chamber roughing valve, is disposed along the second fluid line 202, and is disposed between the second fluid inlet 110b and the second fluid outlet 114b.

The APC module 208 is configured to control a flow of a fluid therethrough. The APC module 208 may comprise a movable valve with a controller. The movable valve of the APC module 208 may comprise a moving pendulum controllable by the controller of the APC module 208 to increase or decrease the size of the orifice in the chamber exhaust path. The APC module 208 may receive a pressure setpoint and an actual pressure reading of the pressure inside the process chamber 108. The controller of the APC module 208 may then control the pendulum according to a control algorithm until the actual pressure measurement matches the setpoint. In some examples, the valve of the APC module 208 may be controlled by the valve controller 118.

The turbopump 210 is coupled to a respective process chamber 108 via the first fluid inlet 110a. The turbopump 210 is configured to pump exhaust gases from the process chamber 108, through the first fluid line 200, and out of the first fluid outlet 114a.

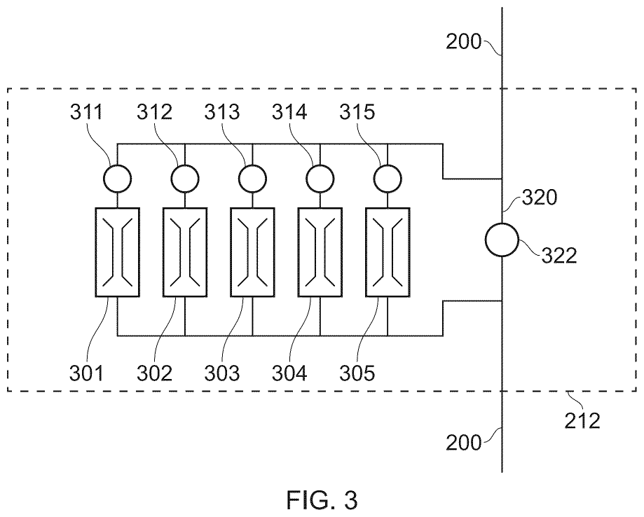

The restrictor module 212 is described in more detail later below with reference to FIG. 3.

The pressure sensor 214 is configured to measure a pressure of the fluid in the first fluid line 200 that is flowing out of the restrictor module 212. The pressure sensor 214 may be operatively coupled to the valve controller 118 such that pressure measurements taken by the pressure sensor 214 may be received by the valve controller 118.

The valve 216 is configured to control a flow of fluid therethrough. In particular, in this example, the valve 216 is configured to be controlled, by the valve controller 118, to selectably permit or prevent a flow of fluid therethrough.

FIG. 3 is a schematic illustration (not to scale) showing further details of a restrictor module 212. In this example, the restrictor modules 212 of the pumping modules 112 are substantially the same as each other.

The restrictor module 212 comprises a plurality of restrictors. In particular, the restrictor module 212 comprises a first restrictor 301, a second restrictor 302, a third restrictor 303, a fourth restrictor 304, and a fifth restrictor 305. The restrictors 301-305 are disposed along the first fluid line 200. The restrictors 301-305 are arranged in parallel with each other.

Each restrictor 301-305 is configured to restrict a flow of fluid therethrough. In particular, in this example, each restrictor 301-305 comprises a flow restricting orifice.

In this example, each restrictor 301-305 is configured to restrict a flow of fluid therethrough to a different extent. Each restrictor 301-305 comprises a flow restricting orifice having a different respective diameter. That is to say, the diameters of the flow restricting orifices of the restrictor 301-305 are different sizes from one another. The diameters of the flow restricting orifices of the restrictors 301-305 may be any appropriate sizes, e.g. sizes selected from a group of values consisting of: 0.5 mm, 0.6 mm, 0.75 mm, 1 mm, and 2 mm. In this example, the first restrictor 301 has a diameter of 0.5 mm, the second restrictor 302 has a diameter of 0.6 mm, the third restrictor 303 has a diameter of 0.75 mm, the fourth restrictor 304 has a diameter of 1 mm, and the fifth restrictor 305 has a diameter of 2 mm.

The restrictor module 212 further comprises means configured to selectably direct a fluid flow through a selected one or more of the restrictors 301-305 while preventing the flow of fluid through the others of the restrictors 301-305. In this example, said means for selectably directing fluid flow through a selected one or more of the restrictors 301-305 comprises a plurality of valves, hereinafter called “restrictor valves”. In particular, the restrictor module 212 comprises a first restrictor valve 311, a second restrictor valve 312, a third restrictor valve 313, a fourth restrictor valve 314, and a fifth restrictor valve 315. Each restrictor valve 311-315 is fluidly coupled in series with a respective restrictor 301-305. In particular, the first restrictor valve 311 is connected in series with the first restrictor 301, the second restrictor valve 312 is connected in series with the second restrictor 302, the third restrictor valve 313 is connected in series with the third restrictor 303, the fourth restrictor valve 314 is connected in series with the fourth restrictor 304, and the fifth restrictor valve 315 is connected in series with the fifth restrictor 305. The series-connected pairs of restrictors and restrictor valves are connected in parallel with each other.

Each restrictor valve 311-315 is configured to control a flow of fluid therethrough. In particular, in this example, each restrictor valve 311-315 is configured to be controlled, by the valve controller 118, to selectably permit or prevent a flow of fluid therethrough. Thus, each restrictor valve 311-315 can selectably allow or prevent fluid flow through the respective restrictor 301-305 coupled in series thereto.

In this example, the restrictor module 212 further comprises a bypass line 320. The bypass line 320 is arranged in parallel with the plurality of restrictors 301-305 (and restrictor valves 311-315). The bypass line 320 is arranged to allow a flow of fluid to bypass the plurality of restrictors 301-305. The bypass line 320 allows a flow of fluid to avoid the plurality of restrictors 301-305 and flow between the turbopump 210 and the first fluid outlet 114a relatively unrestricted.

In this example, the restrictor module 212 further comprises a valve, hereinafter referred to as a “bypass valve 322”. The bypass valve 322 is disposed along the bypass line 320. The bypass valve 322 is configured to control a flow of fluid therethrough. In particular, in this example, the bypass valve 322 is configured to be controlled, by the valve controller 118, to selectably permit or prevent a flow of fluid therethrough. Thus, the bypass valve 322 can selectably allow or prevent fluid flow through the bypass line 320.

The restrictor module 212 may be oriented vertically, i.e. such that process fluid flows though the restrictors in a vertically downwards direction. This orientation and arrangement of the restrictor module 212 tends to prevent blockage of the restrictors 301-305, for example by liquid, which may flow out of the restrictors 301-305 under gravity.

Apparatus, including the valve controller 118, for implementing the above arrangement, and performing the method steps to be described below, may be provided by configuring or adapting any suitable apparatus, for example one or more computers or other processing apparatus or processors, and/or providing additional modules. The apparatus may comprise a computer, a network of computers, or one or more processors, for implementing instructions and using data, including instructions and data in the form of a computer program or plurality of computer programs stored in or on a machine-readable storage medium such as computer memory, a computer disk, ROM, PROM etc., or any combination of these or other storage media.

The above-described system may undergo a pump-down event to evacuate gas from one or more of the process chambers 108, which may be at atmospheric pressure, to reduce the pressure therein to a level suitable for a semiconductor fabrication process. The pump-down event may be performed to evacuate gas from a pumping chamber of the turbopump of one or more of the pumping modules.

What will now be described, with reference to FIGS. 4 to 6, is a process of pumping gas in the semiconductor fabrication facility 100, including a pump down event.

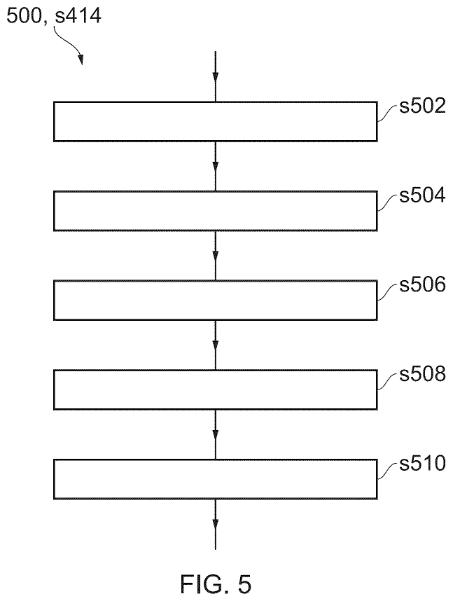

The process steps depicted in the flowcharts of FIGS. 4 and 5 and described below may be omitted or such process steps may be performed in differing order to that presented below and shown in FIGS. 4 and 5. Furthermore, although the process steps have, for convenience and ease of understanding, been depicted as discrete temporally-sequential steps, nevertheless some of the process steps may in fact be performed simultaneously or at least overlapping to some extent temporally.

FIG. 4 is a process flow chart showing steps of a process 400 of pumping gas in the semiconductor fabrication facility 100, including a pump down event.

At step s402, semiconductor fabrication processes are performed in the process chambers 108. These semiconductor fabrication processes generate process gases.

In this example, at this stage, for each of the pumping modules 112, the valves 216 are closed, the restrictor valves 311-315 are closed, and the bypass valves 322 are open. Thus, at step s402, the first vacuum pump 106 pumps process gases out of the process chambers 108 through the relatively unrestricted first fluid lines 200 of the pumping modules 112, and into the first fluid line manifold 116.

At step s404, one of the process chambers 108 (hereinafter referred to as “the first process chamber 108” for convenience) is shut down for inspection, servicing, repair, or maintenance. In this example, the shutting down of the first process chamber 108 comprises stopping pumping gas from the first process chamber 108. In this example, this is achieved by closing the bypass valve 322 of the pumping module 112 associated with the first process chamber 108. The turbopump 210 of the pumping module 112 associated with the first process chamber 108 is also shut down. In this example, the shutting down the first process chamber 108 further comprises increasing the pressure in the first process chamber 108 to approximately atmospheric pressure. This may be achieved by opening a valve coupled to the first process chamber 108, thereby allowing air to enter into the first process chamber 108. In addition, in this example, the pressure in the pumping chamber of the turbopump 210 of the pumping module 112 associated with the first process chamber 108 is also increased to approximately atmospheric pressure.

At step s406, a human operator performs an inspection, servicing, repair, or maintenance operation on the first process chamber 108. Alternatively, or in addition, inspection, servicing, repair, or maintenance may be performed on one or more components of the pumping module 112 associated with the first process chamber 108.

Following the inspection, servicing, repair, or maintenance operation, a low gas pressure environment is to be re-established in the first process chamber 108 such that semiconductor fabrication processes may be performed therein.

Accordingly, at step s408, the valve 216 of the pumping module 112 associated with the first process chamber 108 is opened by the valve controller 118.

At step s410, with the valve 216 open, the second vacuum pump 107 pumps gases along the second fluid line 202 from the first process chamber 108 into the second fluid line manifold 122.

Thus, the first process chamber 108 is “pumped-down”. This gas flow from the first process chamber 108 is independent of gas flow through the first fluid line manifold 116. Advantageously, this separation of flows tends to reduce or eliminate the pumping-down of the first process chamber 108 detrimentally affecting the conditions within parallel process chambers 108.

At step s412, in response to the pumping down of the first process chamber 108 being completed, the valve controller 118 closes the valve 216 of the pumping module 112 associated with the first process chamber 108.

The completion of the pumping down of the first process chamber 108 may be detected by any appropriate means. For example, the valve controller 118 may determine that the pumping-down of the first process chamber 108 is complete in response to a measurement of a pressure within the first process chamber 108 being at or below a first threshold value and/or a calculated rate of decrease of the measured pressure associated with the first process chamber 108 being at or below a second threshold value. The first threshold value may be any appropriate threshold value. The second threshold value may be any appropriate threshold value.

At step s414, in response to the pumping down of the first process chamber 108 being completed, the valve controller 118 controls the restrictors valves 311-315 to open in a predefined sequence. Thus, at step s414 the restrictor valves 311-315 are open and closed in a predefined pattern.

In some examples, at step s414, the valve controller 118 may also control the APC module 208 to prevent or oppose a flow of fluid therethrough.

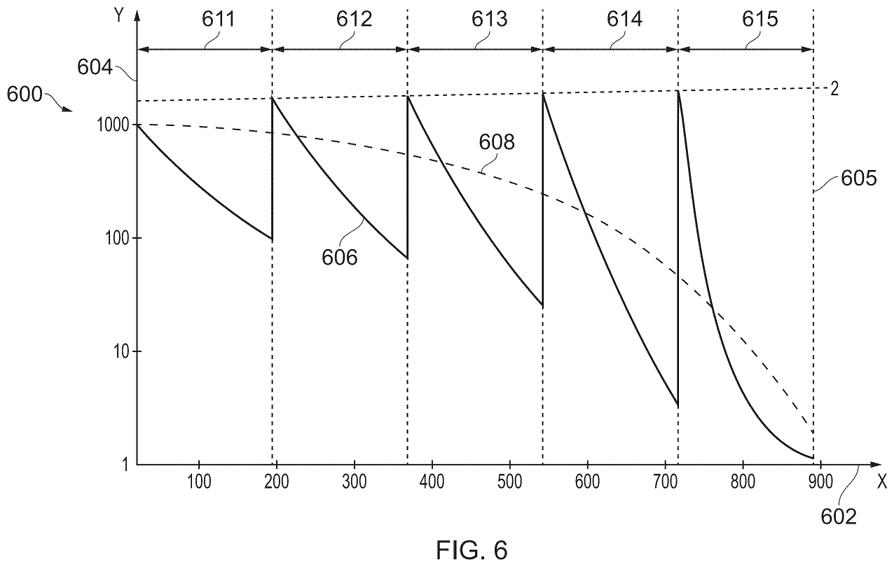

FIG. 5 is a process flow chart showing steps of a process 500 of operating the restrictor valves 311-315, which may be performed at step s414. FIG. 6 is a schematic illustration (not to scale) illustrating operation of the restrictor valves 311-315. The remaining steps of FIG. 4 will be described in more detail later below after the descriptions of FIGS. 5 and 6.

At step s502, the first restrictor valve 311 is opened. At step s502, the remaining restrictor valves 312-315 and the bypass valve 322 are closed. With the first restrictor valve 311 open, fluid flow is directed through the first restrictor 301, which in this example has the smallest diameter, that diameter being 0.5 mm. Fluid does not flow through the other restrictors 302-305 or the bypass line 320. Thus, at step s502, the first vacuum pump 106 pumps gases along the first fluid line 200, from the pumping chamber of the turbopump 210, into the first fluid line manifold 116, via the first restrictor 301.

At step s504, the first restrictor valve 311 is closed and the second restrictor valve 312 is opened. At step s504, the first and third through fifth restrictor valves 311, 313-315 and the bypass valve 322 are closed. With the second restrictor valve 312 open, fluid flow is directed through the second restrictor 302, which in this example has a diameter larger than the first restrictor 301, that diameter being 0.6 mm. Fluid does not flow through the other restrictors 301, 303-305 or the bypass line 320. Thus, at step s504, the first vacuum pump 106 pumps gases along the first fluid line 200, from the pumping chamber of the turbopump 210, into the first fluid line manifold 116, via the second restrictor 302.

At step s506, the second restrictor valve 312 is closed and the third restrictor valve 313 is opened. At step s506, the first, second, fourth, and fifth restrictor valves 311, 312, 314, 315 and the bypass valve 322 are closed. With the third restrictor valve 313 open, fluid flow is directed through the third restrictor 303, which in this example has a diameter larger than the second restrictor 302, that diameter being 0.75 mm. Fluid does not flow through the other restrictors 301, 303, 304, 305 or the bypass line 320. Thus, at step s506, the first vacuum pump 106 pumps gases along the first fluid line 200, from the pumping chamber of the turbopump 210, into the first fluid line manifold 116, via the third restrictor 303.

At step s508, the third restrictor valve 313 is closed and the fourth restrictor valve 314 is opened. At step s508, the first through third, and the fifth restrictor valves 311-313, 315 and the bypass valve 322 are closed. With the fourth restrictor valve 314 open, fluid flow is directed through the fourth restrictor 304, which in this example has a diameter larger than the third restrictor 303, that diameter being 1 mm. Fluid does not flow through the other restrictors 301-303, 305 or the bypass line 320. Thus, at step s508, the first vacuum pump 106 pumps gases along the first fluid line 200, from the pumping chamber of the turbopump 210, into the first fluid line manifold 116, via the fourth restrictor 304.

At step s510, the fourth restrictor valve 314 is closed and the fifth restrictor valve 315 is opened. At step s510, the first through fourth restrictor valves 311-314 and the bypass valve 322 are closed. With the fifth restrictor valve 315 open, fluid flow is directed through the fifth restrictor 305, which in this example has a diameter larger than the fourth restrictor 304, that diameter being 2 mm. Fluid does not flow through the other restrictors 301-304 or the bypass line 320. Thus, at step s510, the first vacuum pump 106 pumps gases along the first fluid line 200, from the pumping chamber of the turbopump 210, into the first fluid line manifold 116, via the fifth restrictor 305.

FIG. 6 is a schematic illustration (not to scale) showing a graph 600 relating to the process of FIG. 5.

The x-axis 602 of the graph 600 is indicative of time, with units in seconds(s).

The primary y-axis 604 of the graph 600 is indicative of pressure (i.e. pressure in the turbopump), with units in mbar.

The secondary y-axis 605 of the graph 600 is indicative of gas flow, with units in standard litre per minute (slm).

The graph 600 comprises two plotted lines, namely a first line 606 and a second line 608. The first line 606 is solid line. The second line 608 is a dashed line. The first line 606 shows a chamber pressure within the pumping chamber of the turbopump 210. The second line 608 shows a pressure within a foreline of the pumping system, i.e. within the first fluid inlet 110a.

The x-axis 602 of the graph 600 is portioned or divided into five time intervals, namely a first time interval 611, a second time interval 612, a third time interval 613, a fourth time interval 614, and a fifth time interval 615.

In this example, each time interval is approximately 190 s in duration. However, in other examples, one or more of the time intervals may be a different respective duration other than 190 s.

The first time interval 611 corresponds to step s502. Thus, during the first time interval 611, the first restrictor valve 311 is open and the other restrictor valves 312-315 and the bypass valve 322 are closed. Thus, fluid flows from the pumping chamber of the turbopump 210 through the first restrictor 301.

At the end of the first time interval 611, the second time interval 612 begins. Also, at the end of the first time interval 611/the beginning of the second time interval 612, the first restrictor valve 311 is closed and the second restrictor valve 312 is opened.

The second time interval 612 corresponds to step s504. Thus, during the second time interval 612, the second restrictor valve 312 is open and the other restrictor valves 311, 313-315 and the bypass valve 322 are closed. Thus, fluid flows from the pumping chamber of the turbopump 210 through the second restrictor 302.

At the end of the second time interval 612, the third time interval 613 begins. Also, at the end of the second time interval 612/the beginning of the third time interval 613, the second restrictor valve 312 is closed and the third restrictor valve 313 is opened.

The third time interval 613 corresponds to step s506. Thus, during the third time interval 613, the third restrictor valve 313 is open and the other restrictor valves 311, 312, 314, 315 and the bypass valve 322 are closed. Thus, fluid flows from the pumping chamber of the turbopump 210 through the third restrictor 303.

At the end of the third time interval 613, the fourth time interval 614 begins. Also, at the end of the third time interval 613/beginning of the fourth time interval 614, the third restrictor valve 313 is closed and the fourth restrictor valve 314 is opened.

The fourth time interval 614 corresponds to step s508. Thus, during the fourth time interval 614, the fourth restrictor valve 314 is open and the other restrictor valves 311-313, 315 and the bypass valve 322 are closed. Thus, fluid flows from the pumping chamber of the turbopump 210 through the fourth restrictor 304.

At the end of the fourth time interval 614, the fifth time interval 615 begins. Also, at the end of the fourth time interval 614/beginning of the fifth time interval 615, the fourth restrictor valve 314 is closed and the fifth restrictor valve 315 is opened.

The fifth time interval 615 corresponds to step s510. Thus, during the fifth time interval 615, the fifth restrictor valve 315 is open and the other restrictor valves 311-314 and the bypass valve 322 are closed. Thus, fluid flows from the pumping chamber of the turbopump 210 through the fifth restrictor 305.

At the end of the fifth time interval 615, the fifth restrictor valve 315 is closed.

At the end of the fifth time interval 615, the pressure within the pumping chamber of the turbopump 210 tends to less than or equal to a threshold value, e.g. 2 mbar, 3 mbar, 4 mbar, 5 mbar, 6 mbar, 7 mbar, 8 mbar, 9 mbar, or 10 mbar.

Thus, the pumping chamber of the turbopump 210 is “pumped-down”. This gas flow from the pumping chamber of the turbopump 210 is restricted by, in sequence, the first through fifth restrictors 301-305. Advantageously, this flow restriction by the restrictors 301-305 tends to reduce or eliminate the pumping-down of the pumping chamber of the turbopump 210 detrimentally affecting the conditions within parallel process chambers 108. In addition, pumping down the pumping chamber of the turbopump 210 sequentially through restrictors of increasing size advantageously tends to provide for faster pumping down of said pumping chamber, for example, compared to if a single restrictor of fixed size was used.

In this example, as shown in the graph 600, the process flow through each chamber 108 is limited to 2 slm (max). This tends to prevent the single vacuum pump being overloaded and unable to provide the vacuum conditions to maintain correct function of the turbo pumps 210. The restrictors are sized to ensure that a turbo pumpdown from atmosphere never exceeds the chamber flow limit of 2 slm. The restrictors are preferably sized to reduce the pressure as fast as possible. In other examples, a different process flow maximum value, other than 2 slm, may be implemented.

At the end of the fifth time interval 615, i.e. after step s510 the process of FIG. 5, step s414 ends, and the process of FIG. 4 proceeds to step s416.

Returning to the description of FIG. 4, at step s416, in response to the pumping down of the pumping chamber of the turbopump 210 being completed, the valve controller 118 controls the fifth restrictor valve 315 to be closed and the bypass valve 322 to be opened. Thus, the flow of fluid is directed through the bypass line 320, and not through the flow restricting portion 301-305 of the restrictor module 212.

In some examples, at step s416, the valve controller 118 may also control the APC module 208 to permit a flow of fluid therethrough.

The completion of the pumping down of the pumping chamber of the turbopump 210 may be detected by any appropriate means. For example, the valve controller 118 may determine that the pumping-down of the pumping chamber of the turbopump 210 is complete in response to a measurement of a pressure within the pumping chamber of the turbopump 210 being at or below a threshold pressure value and/or a calculated rate of decrease of the measured pressure associated with the pumping chamber of the turbopump 210 being at or below a threshold rate value. The threshold pressure value may be any appropriate threshold valve, e.g. 2 mbar, 3 mbar, 4 mbar, 5 mbar, 6 mbar, 7 mbar, 8 mbar, 9 mbar, or 10 mbar. The threshold rate value may be any appropriate threshold valve. The valve controller 118 may determine that the pumping-down of the pumping chamber of the turbopump 210 is complete based on measurements taken by the pressure sensor 214, and/or any other pressure sensor (e.g. a pressure sensor arranged to measure a pressure within the pumping chamber of the turbopump 210).

At step s418, following the bypass valve 322 being controlled to direct the flow of fluid through the bypass line 320, semiconductor fabrication processes may be performed in the first process chamber 108. These semiconductor fabrication processes generate process gases.

At step s420, the first vacuum pump 106 pumps gases out of the first process chamber 108 through the relatively unrestricted first fluid line 200 of the pumping module 112 associated therewith, and into the first fluid line manifold 116.

Thus, a process 400 of pumping gas in the semiconductor fabrication facility 100 is provided.

The above-described system and method advantageously tends to reduce or eliminate pump-down events detrimentally affecting the conditions within parallel process chambers. This tends to be achieved by pumping pump-down gases via restrictors, i.e. restricted conduits or reduced diameter orifices.

Advantageously, by pumping pump-down gases via increasing diameter restrictors in sequence, pump down can be performed relatively quickly.

Advantageously, pump-down events, and the ending of pump-down events, tend to be detected and mitigated against automatically.

Advantageously, the above-described fluid routing module may be integrated in-line with horizontal manifolds connecting the semiconductor processing tool to the vacuum pumps.

Advantageously, the above-described fluid routing module tends to be robust. The vacuum module may be fully assembled, leak-checked, and pre-tested, for example, off-site prior to delivery to a semiconductor fabrication facility, or on-site when delivered. This tends to simplify the installation process and reduce installation time.

Advantageously, the above-described fluid routing module tends to be modular and scalable.

Advantageously, the components in the gas streams of the fluid routing module tend to be easy to service, repair or replace.

Advantageously, the status and operating condition of the system tends to be easily monitorable, for example, either via a Human Machine Interface of the valve module or remotely.

Advantageously, each fluid routing module in a system tends to be easily controllable by a system controller, for example using a communication protocol such as EtherCAT or ethernet.

Advantageously, the above-described fluid routing module allows for multiple mounting options. For example, the fluid routing module may be suspended from a ceiling of a semiconductor fabrication facility, which provides a benefit of not consuming floor space. Alternatively, the fluid routing module can be mounted in a floor-standing rack or on top of other equipment.

In the above examples, the fluid routing module is implemented in a semiconductor fabrication facility for routing pumped process gases. However, in other examples, the fluid routing module may be implemented in a different system and be used for routing a different type of fluid.

In the above examples, there is a single semiconductor processing tool which comprises six process chambers. However, in other examples, there is more than one semiconductor processing tool. One or more of the semiconductor processing tools may comprise a different number of process chambers other than six.

In the above examples, there is a single fluid routing module comprising six pumping modules. However, in other examples, there may be a different number of fluid routing modules, i.e. multiple fluid routing modules. In some examples, one or more of the fluid routing modules may comprise a different number of pumping modules other than six.

In the above examples, a pumping module comprises two inlets connected to two outlets. However, in other examples, one or more of the pumping modules comprises a different number of inlets (other than two) and a different number of outlets (other than two). By way of example, a pumping module may comprise two inlets coupled to a single common outlet.

In the above examples, each pumping module comprises a restrictor module having a plurality of restrictors disposed along the first fluid line between the first fluid inlet and the fluid outlet. The restrictors are arranged in parallel with each other. Thereby, the above-described functionality is provided. However, in other examples, the restrictor module is configured to variably restrict a flow of fluid between the first fluid inlet and the first fluid outlet in a different way. For example, in some examples, the restrictor module comprises one or mare variable restrictors, i.e. one or more restrictors that can each be controlled so as to vary the extent to which they restrict a flow of a fluid therethrough.

In the above examples, each restrictor of the plurality of restrictors is coupled in series to a respective restrictor valve. In addition, a bypass valve is arranged in parallel with the restrictor valves. However, in other examples, one or more of the restrictor and/or bypass valves may be replaced by a different arrangement or configuration of valves providing the above-described functionality. For example, in some examples, multiple of the valves (i.e. restrictor valves and/or bypass valve) may be replaced by a multi-way valve disposed at the junction of corresponding fluid lines. This multi-way valve may be configured to direct fluid along a selected one or more of the corresponding fluid lines.

In the above examples, the pumping chamber of the turbopump is pumped down via the restrictor module. However, in other examples, a different entity (e.g. a process chamber) is pumped down via the restrictor module instead of or in addition to the pumping chamber of the turbopump.

In the above examples, the pumping chamber of the turbopump is pumped down using restriction orifices of monotonically increasing size. However, in other examples, the restriction orifices are not monotonically increased in size, e.g. restriction orifices may be decreased in size responsive to some criterion being met, such as an effect on a parallel processing chamber.

In the above examples, the fluid flow is switched between passing through different restrictors responsive to a time interval (e.g., 190 s) elapsing. However, in other examples, the fluid flow is switched between passing through different restrictors in response to a different criterion being met, for example in response to a measured pressure within the pumping chamber, or a rate of change (e.g. decrease) of the measured pressure, meeting a predetermined threshold value. Changeover to larger restrictor sizes can be controlled by time and/or vacuum diagnostics of the turbo pump. An optimisation process may be performed to manage maximum throughput versus minimum time to pump down.

In some examples, the APC module may be omitted or replaced by one or more valves.

1. A fluid routing module for a vacuum pumping system, the fluid routing module comprising:
a first fluid inlet;
a first fluid outlet;
a first fluid line coupled between the first fluid inlet and the fluid outlet; and
a restrictor module disposed along the first fluid line between the first fluid inlet and the first fluid outlet, the restrictor module being configured to variably restrict a flow of fluid between the first fluid inlet and the first fluid outlet.

2. The fluid routing module of claim 1, wherein:
the restrictor module comprises a plurality of restrictors disposed along the first fluid line between the first fluid inlet and the fluid outlet, the plurality of restrictors being arranged in parallel with each other, each restrictor of the plurality of restrictors being configured to restrict a flow of fluid therethrough; and
the fluid routing module further comprises means configured to selectably direct a fluid flow through a selected one or more restrictors of the plurality of restrictors while preventing the flow of fluid through the other restrictors of the plurality of restrictors.

3. The fluid routing module of claim 2, wherein the means configured to selectably direct a fluid flow through a selected one or more restrictors comprises a plurality of valves, each valve in the plurality of valves being arranged in series with a respective restrictor of the plurality of restrictors.

4. The fluid routing module of claim 2, further comprising:
a bypass line arranged in parallel with the restrictor module whereby to allow a flow of fluid to bypass the plurality of restrictors; and
one or more further valves configured to selectably direct a fluid flow through either the bypass line or the plurality of restrictors.

5. The fluid routing module of claim 3, further comprising a valve controller configured to control operation of a valve.

6. The fluid routing module of claim 2, wherein each restrictor of the plurality of restrictors is configured to restrict a flow of fluid therethrough to a different extent.

7. The fluid routing module of claim 6, wherein each restrictor of the plurality of restrictors comprises a flow restricting orifice having a different respective diameter.

8. The fluid routing module of claim 1, further comprising a vacuum pump disposed along the first fluid line between the first fluid inlet and the restrictor module.

9. The fluid routing module of claim 8, wherein the vacuum pump is a turbopump.

10. The fluid routing module of claim 1, further comprising:
a second fluid inlet;
a second fluid outlet;
a second fluid line coupled between the second fluid inlet and the fluid outlet; and
one or more valves disposed along the second fluid line.

11. A system comprising:
a semiconductor processing tool comprising a processing chamber;
the fluid routing module of claim 1, wherein the first fluid inlet is fluidly coupled to the processing chamber; and
a vacuum pump operatively coupled to the first fluid outlet.

12. The system of claim 11, wherein:
the semiconductor processing tool further comprises one or more further processing chambers;
the system further comprises one or more further fluid routing modules, each further fluid routing module being a fluid routing module in accordance with claim 1, wherein the first fluid inlets of each further fluid routing module are fluidly coupled to a respective further processing chamber;
the system further comprises a fluid line manifold, wherein the first fluid outlets of the fluid routing module and each of the further fluid routing modules are fluidly coupled to the fluid line manifold; and
the vacuum pump is operatively coupled to the fluid line manifold.

13. The system of claim 11, wherein:
the fluid routing module is in accordance with claim 10; and
the second fluid inlet is fluidly coupled to the processing chamber; and
the system further comprises a further vacuum pump operatively coupled to the second fluid outlet.

14. A method for routing a fluid through a fluid routing module, the fluid routing module being in accordance with claim 1, the method comprising:
receiving a flow of a fluid at the first fluid inlet;
variably restricting, by the restrictor module, the fluid through the restrictor module; and
thereafter, the fluid flowing out of the first fluid outlet.

15. The method of claim 14, wherein:
the fluid routing module further comprises:
a vacuum pump disposed along the first fluid line between the first fluid inlet and the restrictor module;
a bypass line arranged to allow a flow of fluid to a flow restricting portion of the restrictor module; and
means configured to selectably direct a fluid flow through the bypass line;
the method further comprises, responsive to one or more conditions being satisfied, controlling the further means to cause the fluid to flow through the bypass line, thereby bypassing the flow restricting portion of the restrictor module; and
the one or more conditions comprises a condition that a pressure in a pumping chamber of the vacuum pump is below a threshold pressure.
